(19) United States
(12) Patent Application Publication
(10) Pub. No.: US 2014/0368987 A1
(43) Pub. Date: Dec. 18, 2014

(54) INTEGRATED PRINTED CIRCUIT BOARD AND ELECTRONIC DEVICE WITH SAME

(71) Applicants: Hon Hai Precision Industry Co., Ltd., New Taipei (TW); Hong Fu Jin Precision Industry (ShenZhen) Co., Ltd., Shenzhen (CN)

(72) Inventors: XIAO-CONG WEI, Shenzhen (CN); XIAO-ZHAN PENG, Shenzhen (CN)

(73) Assignees: Hon Hai Precision Industry Co., Ltd., New Taipei (TW); Hong Fu Jin Precision Industry (ShenZhen) Co., Ltd., Shenzhen (CN)

(21) Appl. No.: 14/103,857

(22) Filed: Dec. 12, 2013

(30) Foreign Application Priority Data
Jun. 18, 2013 (CN) 2013102410241

(51) Int. Cl. H05K 1/02

(52) U.S. Cl. CPC H05K 1/0286
USPC 361/679.31; 174/261; 361/784

(57) ABSTRACT

An exemplary integrated printed circuit board (PCB) includes a main PCB and a peripheral PCB. The main PCB includes a number of general purpose input/output (GPIO) ports and a number of first bonding pads, the bonding pads are located on edges of the main PCB and each GPIO port is electrically connected to one of the first bonding pads. The peripheral PCB includes a receiving space and a number of second bonding pads, the receiving space is used to receive the main PCB, the second bonding pads are located at inner peripheral edges of the peripheral PCB surrounding the receiving space. When the first bonding pads of the main PCB are respectively welded with the second bonding pads, the main PCB and the peripheral PCB are connected to each other to form the integrated PCB. An electronic device incorporating an integrated PCB is also provided.

### BACKGROUND

1. Technical Field

The present disclosure relates to printed circuit boards, and particularly to an integrated printed circuit board and an electronic device with the integrated printed circuit board.

2. Description of Related Art

A printed circuit board (PCB) is a necessary part of numerous electronic devices. Usually, a PCB includes a single substrate (or board), and a number of components located on the substrate. The components may be a number of chips and a number of peripheral components, for example. In a typical PCB, because all of the components are located on the substrate, when some of the components are changed, the whole PCB needs to be changed or redesigned. This wastes time and is costly.

Thus, a PCB and an electronic device having a PCB which overcome the above-described limitations are needed.

### BRIEF DESCRIPTION OF THE DRAWINGS

Many aspects of the present disclosure are better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the views.

FIG. 1 is a block diagram of an electronic device with an integrated printed circuit board, according to one embodiment of the present invention.

FIG. 2 is a schematic diagram of the integrated printed circuit board of FIG. 1.

FIG. 3 is a schematic diagram of a main printed circuit board of the integrated printed circuit board of FIG. 2.

### DETAILED DESCRIPTION

Embodiments of the present disclosure will be described with reference to the accompanying drawings.

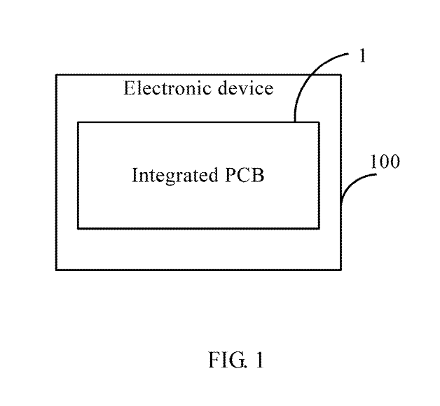

FIG. 1 shows an electronic device 100 of one embodiment. The electronic device 100 includes an integrated printed circuit board (PCB) 1.

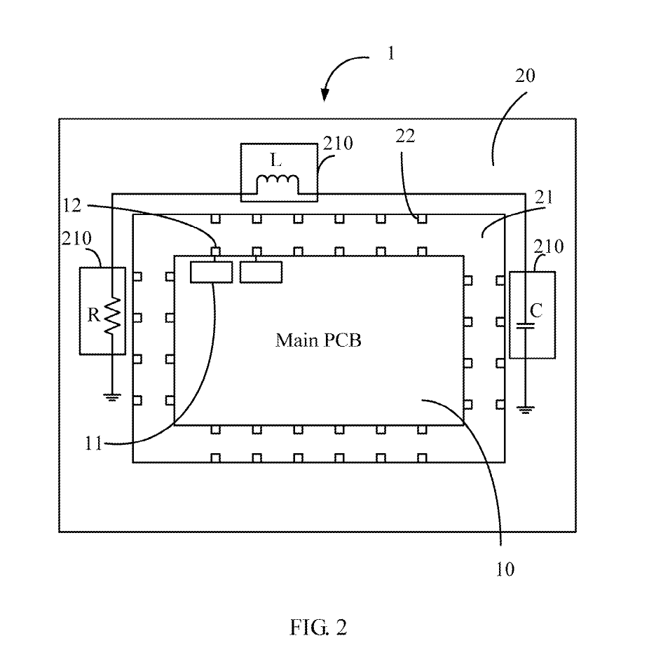

Referring also to FIG. 2, the integrated PCB 1 includes a main PCB 10 and a peripheral PCB 20. The main PCB 10 includes a plurality of general purpose input/output (GPIO) ports 11 and a plurality of bonding pads 12. In the embodiment, the number of GPIO ports 11 is equal to the number of bonding pads 12. The bonding pads 12 are located on edges of the main PCB 10, and each GPIO port 11 is electrically connected to one of the bonding pads 12. For example, as shown in FIG. 2, the main PCB 10 has a rectangular shape. The bonding pads 12 are located on four sides of the main PCB 10, that is, at four outer edges of the main PCB 10. The GPIO ports 11 (only two illustrated) are electrically connected to the bonding pads 12 one-to-one. In the following description, unless the context indicates otherwise, a reference to the “side” of something means, or includes, a reference to the side edge of that thing.

The peripheral PCB 20 includes a receiving space 21 and a plurality of bonding pads 22. The receiving space 21 is used to receive the main PCB 10. The bonding pads 22 are located on an inner periphery of the peripheral PCB 20 where inner sides of the peripheral PCB 20 surround the receiving space 21.

The bonding pads 12 of the main PCB 10 are respectively used to weld with the bonding pads 22 of the peripheral PCB 20 to form the integrated PCB 1. In the embodiment, the bonding pads 12 of the main PCB 10 are respectively welded with the bonding pads 22 of the peripheral PCB 20 according to a surface mount technology method. Typically, the bonding pads 12 of the main PCB 10 are surface mounted on the bonding pads 22 of the peripheral PCB 20.

In the embodiment, a central portion of the peripheral PCB 20 is hollow or is recessed inward to form the receiving space 21. The receiving space 21 is rectangular, to match the shape of the main PCB 10. A size of the receiving space 21 is substantially equal to a size of the main PCB 10. In other embodiments, the main PCB 10 and the receiving space 21 can be any other shape, such as triangular, hexagonal, etc.

As shown in FIG. 2, in the embodiment, the bonding pads 12 are located on four sides of the main PCB 10, and the bonding pads 22 are located at four inner sides of the peripheral PCB 20 at the receiving space 21. In another embodiment, the bonding pads 12 are only located on one or two sides of the main PCB 10, and the bonding pads 22 are only located at one or two corresponding inner sides of the peripheral PCB 20 at the receiving space 21.

In certain embodiments, the number of bonding pads 12 can be 32, 64, or 128. Correspondingly, the number of bonding pads 22 can be 32, 64, or 128.

In the illustrated embodiment, the receiving space 21 is a closed area, and each inner side of the peripheral PCB 20 at the receiving space 21 abuts one corresponding side of the main PCB 10. In other embodiments, the receiving space 21 can be a non-closed area. For example, at least one side of the main PCB 10 does not abut an inner side of the peripheral PCB 20 at the receiving space 21.

In the illustrated embodiment, there is only one main PCB 10. In other embodiments, the integrated PCB 1 can include at least two main PCBs 10.

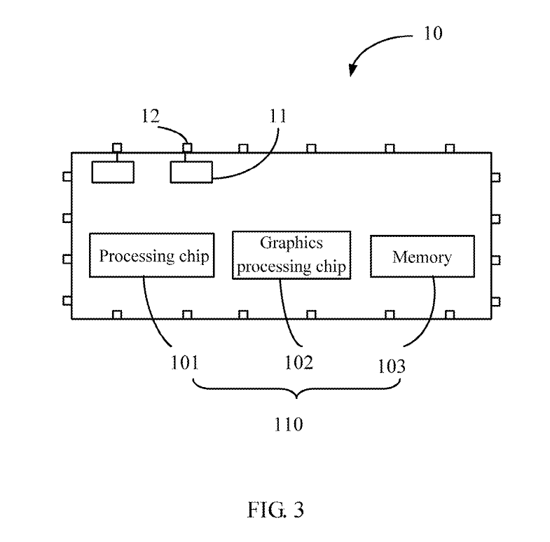

FIG. 3 shows that the main PCB 10 has a number of main chips 110 installed thereon. The main chips 110 include, but are not limited to, a processor 101, a graphics processing chip 102, and a memory 103. The peripheral PCB 20 has a number of peripheral components 210 installed thereon. The peripheral components 210 include, but are not limited to, a resistor R, a capacitor C, and an inducer L. There may also be one or more auxiliary (or assistant) chips (not shown), such as a voice recognition chip or other chips executing additional functions.

In the embodiment, the GPIO ports 11 are also electrically connected to the main chips 110. Thus when the main PCB 10 is welded with the peripheral PCB 20, the main chips 110 including the processor 101, the graphics processing chip 102, and the memory 103 communicate with the peripheral components 210 via the GPIO ports 11 and the bonding pads 12 and 22.

In the embodiment, when components installed on the peripheral PCB 20 need to be changed but no components on the main PCB 10 need to be changed, it is only necessary to weld a new peripheral PCB 20 with the main PCB 10. That is, unlike in conventional art, there is no need to change or redesign the whole PCB.

The electronic device 100 can be a mobile phone, a tablet computer, a desktop computer, a portable computer, a digital camera, or any other device that includes a PCB.

It is understood that the present embodiments and their advantages will be understood from the foregoing description, and various changes may be made thereto without departing from the spirit and scope of the disclosure or sacrificing all of its material advantages, the examples hereinbefore described merely being preferred or exemplary embodiments.

What is claimed is:

1. An integrated printed circuit board (PCB) comprising:
a main PCB comprising a plurality of general purpose input/output (GPIO) ports and a plurality of first bonding pads, wherein the first bonding pads are located on outer edges of the main PCB, and each GPIO port is electrically connected to one of the first bonding pads; and
a peripheral PCB comprising a receiving space and a plurality of second bonding pads, wherein the receiving space is configured to receive the main PCB, and the second bonding pads are located at inner peripheral edges of the peripheral PCB surrounding the receiving space;
wherein, when the first bonding pads of the main PCB are respectively welded with the second bonding pads of the peripheral PCB, the main PCB and the peripheral PCB are connected to each other to form the integrated PCB.

2. The integrated PCB according to claim 1, wherein the main PCB comprises a plurality of main chips, which comprise items selected from the group consisting of a processing chip, a graphics processing chip, and a memory.

3. The integrated PCB according to claim 2, wherein the peripheral PCB comprises a plurality of peripheral components, which comprise items selected from the group consisting of a resistor, a capacitor, an inducer, and an auxiliary chip.

4. The integrated PCB according to claim 3, wherein the plurality of GPIO ports are further electrically connected to the main chips of the main PCB, and the main chips of the main PCB are electrically connected to the peripheral components of the peripheral PCB via the GPIO ports and the first bonding pads and the second bonding pads.

5. The integrated PCB according to claim 1, wherein when the first bonding pads of the main PCB are respectively welded with the second bonding pads of the peripheral PCB, the first bonding pads are surface mounted on the second bonding pads.

6. The integrated PCB according to claim 1, wherein the main PCB and the receiving space both are rectangular shaped.

7. An integrated printed circuit board (PCB) comprising:
a main PCB comprising a plurality of general purpose input/output (GPIO) ports and a plurality of first bonding pads, wherein the first bonding pads are located on outer edges of the main PCB, and each GPIO port is electrically connected to one of the first bonding pads; and
a peripheral PCB comprising a receiving space receiving the main PCB and a plurality of second bonding pads, wherein the second bonding pads are located at inner peripheral edges of the peripheral PCB surrounding the receiving space and are respectively welded with the first bonding pads of the main PCB.

8. The integrated PCB according to claim 7, wherein the main PCB comprises a plurality of main chips, which comprise items selected from the group consisting of a processing chip, a graphics processing chip, and a memory.

9. The integrated PCB according to claim 8, wherein the peripheral PCB comprises a plurality of peripheral components, which comprise items selected from the group consisting of a resistor, a capacitor, an inducer, and an auxiliary chip.

10. The integrated PCB according to claim 9, wherein the plurality of GPIO ports are further electrically connected to the main chips of the main PCB, and the main chips of the main PCB are electrically connected to the peripheral components of the peripheral PCB via the GPIO ports and the first bonding pads and the second bonding pads.

11. The integrated PCB according to claim 7, wherein the first bonding pads are surface mounted on the second bonding pads.

12. An electronic device comprising:
an integrated printed circuit board (PCB) comprising:
a main PCB comprising a plurality of general purpose input/output (GPIO) ports and a plurality of first bonding pads, wherein the first bonding pads are located on outer edges of the main PCB, and each GPIO port is electrically connected to one of the first bonding pads; and
a peripheral PCB comprising a receiving space receiving the main PCB and a plurality of second bonding pads, wherein the second bonding pads are located at inner peripheral edges of the peripheral PCB surrounding the receiving space and are respectively welded with the first bonding pads of the main PCB.
a main PCB comprising a plurality of general purpose input/output (GPIO) ports and a plurality of first bonding pads, wherein the first bonding pads are located on outer edges of the main PCB, and each GPIO port is electrically connected to one of the first bonding pads; and
a peripheral PCB comprising a receiving space receiving the main PCB and a plurality of second bonding pads, wherein the second bonding pads are located at inner peripheral edges of the peripheral PCB surrounding the receiving space and are respectively welded with the first bonding pads of the main PCB.

13. The electronic device according to claim 12, wherein the main PCB comprises a plurality of main chips, which comprise items selected from the group consisting of a processing chip, a graphics processing chip, and a memory.

14. The electronic device according to claim 13, wherein the peripheral PCB comprises a plurality of peripheral components, which comprise items selected from the group consisting of a resistor, a capacitor, an inducer, and an auxiliary chip.

15. The electronic device according to claim 14, wherein the plurality of GPIO ports are further electrically connected to the main chips of the main PCB, and the main chips of the main PCB are electrically connected to the peripheral components of the peripheral PCB via the GPIO ports and the first bonding pads and the second bonding pads.

16. The electronic device according to claim 12, wherein the first bonding pads are surface mounted on the second bonding pads.

17. The electronic device according to claim 12, wherein the electronic device is one selected from a group consisting of a mobile phone, a table computer, a desktop computer, a portable computer, and a digital camera.
